(19) United States
(12) Patent Application Publication
(10) Pub. No.: US 2007/0170579 A1
(43) Pub. Date: Jul. 26, 2007

(54) Method of manufacturing semiconductor substrate, method of manufacturing semiconductor device, and semiconductor device

(75) Inventor: Toshiki Hara, Suwa-shi (JP)

Correspondence Address: ADVANTEDGE LAW GROUP, LLC, 1928 E. COBBLESTONE RD., SUITE 100, SPRINGVILLE, UT, 84663, US

(73) Assignee: Seiko Epson Corporation, Tokyo (JP)

(21) Appl. No.: 11/653,509

(22) Filed: Jan. 16, 2007

(30) Foreign Application Priority Data
Jan. 24, 2006 (JP) 2006-015366

(51) Int. Cl. H01L 23/12

(52) U.S. Cl. 257/704

(57) ABSTRACT

A method of manufacturing a semiconductor substrate includes: forming on a semiconductor base a first isolation layer for isolating an element region from another region; forming a first semiconductor layer on the semiconductor base; forming a second semiconductor layer on the first semiconductor layer, the second semiconductor layer having an etch selectivity less than that of the first semiconductor layer; forming a support hole by removing a portion of the second semiconductor layer and a portion of the first semiconductor layer each corresponding to the support hole; forming a support formation layer above the semiconductor base so as to cover the support hole and the second semiconductor layer; forming a support and an exposed surface for exposing part of an end of each of the first semiconductor layer and the second semiconductor layer by etching an area other than that including the support hole and the element region therein, the first semiconductor layer and the second semiconductor layer being located under the support; forming a cavity between the second semiconductor layer in the element region and the semiconductor base by etching away the first semiconductor layer through the exposed surface; forming a buried insulating layer in the cavity; and performing planarization above the second semiconductor layer to remove part of the support located on the second semiconductor layer; wherein the forming a support hole forms a first support hole at the boundary between the element region and the first isolation layer.

### BACKGROUND OF THE INVENTION

1. Technical Field

The present invention relates to a method of manufacturing a semiconductor substrate, a method of manufacturing a semiconductor device, and a semiconductor device, and particularly relates to a technique of forming a Silicon On Insulator (SOI) structure on a semiconductor substrate.

2. Related Art

The above-mentioned method of manufacturing a semiconductor substrate partially forms an SOI layer on the bulk silicon substrate and further forms an SOI transistor on the SOI layer using Separation by Bonding Si Islands (SBSI), for example as described in an example of related art, T. Sakai et al., Second International SiGe Technology and Device Meeting, Meeting Abstract, pp. 230-231, May (2004).

The partial formation of the SOI layer on the bulk silicon substrate allows, for example, forming the SOI transistor at low cost.

A method of forming an SOI structure on the bulk silicon substrate according to the SBSI mentioned above will be described with reference to FIGS. 11A and 11B.

Initially, a silicon germanium (SiGe) layer and a silicon (Si) layer are epitaxially grown on a bulk silicon substrate 103 and forms support holes for forming a support in an element region in which an SOI layer is formed.

An oxide film or the like is formed over the layers and the support holes, and thereafter the oxide film, the silicon layer and the silicon germanium layer to be located in the vicinity of an element formation region are dry etched so as to establish the shape of the element formation region.

Then, when the silicon germanium layer is selectively etched with fluoro-nitric acid, a cavity is formed under a silicon layer 101, which is supported by a support 102.

An insulating layer made of SiO₂ or the like is buried into the cavity to form a BOX (Buried Oxide) layer 104 between the bulk silicon substrate 103 and the silicon layer 101.

Thereafter, the surface of the bulk silicon substrate 103 is planarized to expose the silicon layer 101, thus forming an SOI structure on the bulk silicon substrate 103.

The planarization is performed by Chemical Mechanical Polishing (CMP), for example.

In the planarization performed by CMP, however, when etching is performed using a polycrystallinelized epitaxial film (not shown) on a first isolation layer 105 as a stopper layer, a portion of the silicon layer 101 to be left behind may be excessively etched away because an element region 106 for SOI structure (refer to FIG. 11A) on the bulk silicon substrate 103 is large.

Therefore, in order to actually form an SOI structure on a bulk silicon substrate using SBSI, excessive etching of the silicon layer 101 need be suppressed by, for example, forming a second isolation layer 107 serving as a stopper layer in the element region 106 as shown in FIGS. 11A and 11B.

However, forming the second isolation layer 107 in the element region 106 reduces an area of the element region 106 in which an element can be formed, causing a need for expanding the element region 106 up to the required size.

This poses a problem of increasing the size (area) of a semiconductor substrate 108.

Additionally, another problem is that the number of the semiconductor substrates 108 that can be made from one substrate is decreased.

### SUMMARY

An advantage of the invention is to provide a method of manufacturing a semiconductor substrate, a method of manufacturing a semiconductor device, and a semiconductor device that allow a smaller semiconductor substrate (with smaller area) to be manufactured.

A method of manufacturing a semiconductor substrate according to a first aspect of the invention includes: forming on a semiconductor base a first isolation layer for isolating an element region from another region; forming a first semiconductor layer on the semiconductor base; forming a second semiconductor layer on the first semiconductor layer, the second semiconductor layer having an etch selectivity less than that of the first semiconductor layer; forming a support hole by removing a portion of the second semiconductor layer and a portion of the first semiconductor layer each corresponding to the support hole; forming a support formation layer above the semiconductor base so as to cover the support hole and the second semiconductor layer; forming a support and an exposed surface for exposing part of an end of each of the first semiconductor layer and the second semiconductor layer by etching an area other than that including the support hole and the element region therein, the first semiconductor layer and the second semiconductor layer being located under the support; forming a cavity between the second semiconductor layer in the element region and the semiconductor base by etching away the first semiconductor layer through the exposed surface; forming a buried insulating layer in the cavity; and performing planarization above the second semiconductor layer to remove part of the support located on the second semiconductor layer; wherein the forming a support hole forms a first support hole at the boundary between the element region and the first isolation layer.

Accordingly, the first support hole is formed at the boundary of the first isolation layer and the element region, making it possible for the area of the first support hole occupied in the element region (the area of the portion of the first support hole located within the element region) to be made small as compared to the case where the first support hole is formed within the element region.

This enables the area of the element region to be made smaller, thereby making the semiconductor substrate smaller.

In addition, the number of the semiconductor substrates that can be made from one substrate can be increased.

A method of manufacturing a semiconductor substrate according to a second aspect of the invention includes: forming on a semiconductor base a first isolation layer for isolating an element region from another region and forming within the element region a second isolation layer for being used as a stopper layer; forming a first semiconductor layer on the semiconductor base; forming a second semiconductor layer on the first semiconductor layer, the second semiconductor layer having an etch selectivity less than that of the first semiconductor layer; forming a support hole by removing a portion of the second semiconductor layer and a portion of the first semiconductor layer each corresponding to the support hole; forming a support formation layer above the semiconductor base so as to bury the support hole and to cover the second semiconductor layer; forming a support and an exposed surface for exposing part of an end of each of the first semiconductor layer and the second semiconductor layer by etching an area other than that including the support hole and the element region therein, the first semiconductor layer and the second semiconductor layer being located under the support; forming a cavity between the second semiconductor layer in the element region and the semiconductor base by etching away the first semiconductor layer through the exposed surface; forming a buried insulating layer in the cavity; and performing planarization above the second semiconductor layer by using at least the second isolation layer to remove part of the support located on the second semiconductor layer; wherein the forming a support hole forms a first support hole at the boundary between the element region and the first isolation layer.

Accordingly, the first support hole is formed at the boundary of the first isolation layer and the element region, making it possible for the area of the first support hole occupied in the element region (the area of the portion of the first support hole located within the element region) to be made small as compared to the case where the first support hole is formed within the element region.

This enables the area of the element region to be made smaller, thereby making the semiconductor substrate smaller.

In addition, the number of the semiconductor substrates that can be made from one substrate can be increased.

Moreover, forming the second isolation layer within the element region can suppress excessive removal of the second semiconductor layer when planarization is performed.

In the above-mentioned method according to the second aspect of the invention, it is preferable that the process of forming a support hole form a second support hole in an area including the second isolation layer.

Accordingly, the second support hole is formed in the area including the second isolation layer, allowing the support to be formed based on the second support hole and the first support hole located at the boundary.

The second semiconductor layer can be supported by the support.

In the above-mentioned method according to the first aspect of the invention, it is preferable that the first semiconductor layer be a silicon germanium layer, and the second semiconductor layer be a silicon layer.

Accordingly, silicon has an etch selectivity less than that of silicon germanium, and therefore selective etching can be performed to remove the silicon germanium layer, leaving behind the silicon layer.

This allows forming under the silicon layer a cavity that is to be buried to form a buried insulating layer.

A method of manufacturing a semiconductor device according to a third aspect of the invention includes forming a transistor in the second semiconductor layer after performing the above-mentioned method of manufacturing a semiconductor substrate according to the first aspect of the invention.

Accordingly, it is possible to provide a method of manufacturing a semiconductor device by which a semiconductor device with a transistor can be manufactured to be smaller.

A semiconductor device according to a fourth aspect of the invention includes an SOI structure that has a buried insulating layer formed on a semiconductor base, the buried insulating layer being buried to replace a first semiconductor layer; a second semiconductor layer formed on the buried insulating layer; and a support for supporting the second semiconductor layer; wherein a first support hole for forming the support is formed at the boundary of an element region and a first isolation layer.

Accordingly, the first support hole is formed at the boundary of the first isolation layer and the element region, making it possible for the area of the first support hole occupied in the element region (the area of the portion of the first support hole located within the element region) to be made small as compared to the case where the first support hole is formed within the element region.

This enables the area of the element region to be made smaller, thereby making the semiconductor substrate smaller.

In addition, the number of the semiconductor substrates that can be made from one substrate can be increased.

### BRIEF DESCRIPTION OF THE DRAWINGS

The invention will be described with reference to the accompanying drawings, wherein like numbers reference like elements.

FIGS. 1A and 1B are schematic views showing a method of manufacturing a semiconductor substrate following the process flow of one embodiment of the invention; FIG. 1A is a schematic plan view showing the manufacturing method of a semiconductor substrate, and FIG. 1B a schematic sectional view showing the manufacturing method of a semiconductor substrate.

FIGS. 2A and 2B are schematic views showing the method of manufacturing a semiconductor substrate; FIG. 2A is a schematic plan view showing the manufacturing method of a semiconductor substrate, and FIG. 2B is a schematic sectional view showing the manufacturing method of a semiconductor substrate.

FIGS. 3A and 3B are schematic views showing the method of manufacturing a semiconductor substrate; FIG. 3A is a schematic plan view showing the manufacturing method of a semiconductor substrate, and FIG. 3B is a schematic sectional view showing the manufacturing method of a semiconductor substrate.

FIGS. 4A and 4B are schematic views showing the method of manufacturing a semiconductor substrate; FIG. 4A is a schematic plan view showing the manufacturing method of a semiconductor substrate, and FIG. 4B is a schematic sectional view showing the manufacturing method of a semiconductor substrate.

FIGS. 5A and 5B are schematic views showing the method of manufacturing a semiconductor substrate; FIG. 5A is a schematic plan view showing the manufacturing method of a semiconductor substrate, and FIG. 5B is a schematic sectional view showing the manufacturing method of a semiconductor substrate.

FIGS. 6A and 6B are schematic views showing the method of manufacturing a semiconductor substrate; FIG. 6A is a schematic plan view showing the manufacturing method of a semiconductor substrate, and FIG. 6B is a schematic sectional view showing the manufacturing method of a semiconductor substrate.

FIGS. 7A and 7B are schematic views showing the method of manufacturing a semiconductor substrate; FIG. 7A is a schematic plan view showing the manufacturing method of a semiconductor substrate, and FIG. 7B is a schematic sectional view showing the manufacturing method of a semiconductor substrate.

FIGS. 8A and 8B are schematic views showing the method of manufacturing a semiconductor substrate; FIG. 8A is a schematic plan view showing the manufacturing method of a semiconductor substrate, and FIG. 8B is a schematic sectional view showing the manufacturing method of a semiconductor substrate.

FIGS. 9A and 9B are schematic views showing the method of manufacturing a semiconductor substrate; FIG. 9A is a schematic plan view showing the manufacturing method of a semiconductor substrate, and FIG. 9B is a schematic sectional view showing the manufacturing method of a semiconductor substrate.

FIGS. 10A and 10B are schematic views showing a method of manufacturing a semiconductor device and a configuration of the semiconductor device; FIG. 10A is a schematic plan view and FIG. 10B is a schematic sectional view.

FIGS. 11A and 11B are schematic views showing a conventional method of manufacturing a semiconductor substrate; FIG. 11A is a schematic plan view and FIG. 11B is a schematic sectional view.

### DESCRIPTION OF EXEMPLARY EMBODIMENT

An embodiment of a method of manufacturing a semiconductor substrate, a method of manufacturing a semiconductor device, and a semiconductor device according to the invention will now be described.

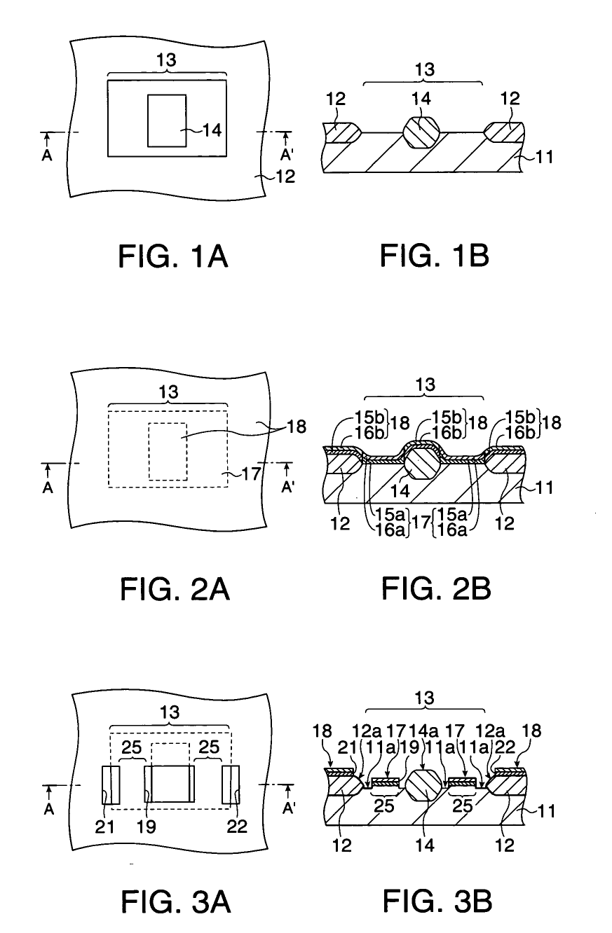

FIGS. 1A through 9B are schematic views showing a method of manufacturing a semiconductor substrate. FIGS. 1A to 9A are schematic plan views, and FIGS. 1B to 9B are schematic sectional views taken along the line A-A′ of FIGS. 1A to 9A, respectively. The method of manufacturing a semiconductor substrate will be described below with reference to FIGS. 1A through 9B.

FIGS. 1A and 1B show a process that forms a first isolation layer 12 and a second isolation layer 14 on a silicon substrate 11 serving as a semiconductor base (bulk silicon substrate).

The first isolation layer 12, which is, for example, an oxide film made by Local Oxidation of Silicon (LOCOS) technique, is formed so as to electrically insulate an SOI element formation region (active region) 13, which serves as an element region where a transistor of SOI structure is to be formed, from a bulk element formation region (not shown), which serves as another region where a transistor of bulk structure is to be formed.

The second isolation layer 14 is the same oxide film as the first isolation layer 12 and serves as a stopper layer in the CMP polishing, which will be described later.

Description on the bulk element formation region will be omitted below.

Initially, a silicon oxide film (SiO₂), which is not shown, is deposited over the entire silicon substrate 11.

Next, a silicon nitride film (SiN), which is also not shown, is deposited over the silicon substrate 11 in the SOI element formation region 13 (excluding the region of the second isolation layer 14) using a photolithography technique.

Thereafter, the silicon substrate 11 is oxidized by using the silicon nitride film as a mask.

The first isolation layer 12 and the second isolation layer 14 are thereby formed on the silicon substrate 11.

FIGS. 2A and 2B show a process that forms a silicon germanium (SiGe) layer 15 serving as a first semiconductor layer and a silicon (Si) layer 16 serving as a second semiconductor layer one atop the other over the entire silicon substrate 11.

Initially, the silicon oxide film (not shown) on the silicon substrate 11 in the SOI element formation region 13 is removed using a photolithography technique.

The silicon substrate 11 is thereby exposed in the SOI element formation region 13 excluding the region of the second isolation layer 14.

Next, the silicon germanium layer 15 as a sacrificial layer and the silicon layer 16 for forming an SOI element are epitaxially grown one atop the other over the entire silicon substrate 11 by an epitaxial growth technique.

A single-crystal epitaxial film 17 to which the crystallinity is transferred from the silicon substrate 11 and which is newly grown is thereby formed on the area where the silicon substrate 11 has been exposed.

The single-crystal epitaxial film 17 consists of a first silicon germanium layer 15a and a first silicon layer 16a that have been grown as single-crystal.

Formed on the first isolation layer 12 and the second isolation layer 14 are polycrystalline epitaxial films 18.

The polycrystalline epitaxial film 18 consists of a second silicon germanium layer 15b and a second silicon layer 16b that have been grown as polycrystalline.

FIGS. 3A and 3B show a process that forms a first support hole 21 and a second support hole 22 serving as the primary support hole at the boundary of the first isolation layer 12 and the SOI element formation region 13, and forms a third support hole 19 that serves as the secondary support hole in an area including the second isolation layer 14 in the SOI element formation region 13.

Initially, a resist pattern (not shown) that opens areas corresponding to the first support hole 21, the second support hole 22 and the third support hole 19 is made using a photolithography technique.

Next, part of the single-crystal epitaxial film 17, part of the polycrystalline epitaxial film 18 and part of the silicon substrate 11 in areas corresponding to the support holes 21, 22 and 19 are etched away by using the resist pattern as a mask.

Thereby, the first support hole 21 and the second support hole 22 are formed at the boundary of the first isolation layer 12 and the SOI element formation region 13, and the third support hole 19 is formed in an area including the second isolation layer 14.

The formation of the first support hole 21, second support hole 22 and third support hole 19 causes the surface 11a of the silicon substrate 11, the surface 12a of the first isolation layer 12 and the surface 14a of the second isolation layer 14 to be exposed.

An area located between the first support hole 21 and the third support hole 19 and an area located between the third support hole 19 and the second support hole 22 constitute element formation regions 25.

As described above, the first support hole 21 and the second support hole 22 are formed at the boundary of the first isolation layer 12 and the SOI element formation region 13.

This location allows smaller areas to be occupied by the first support hole 21 and the second support hole 22 in the SOI element formation region 13.

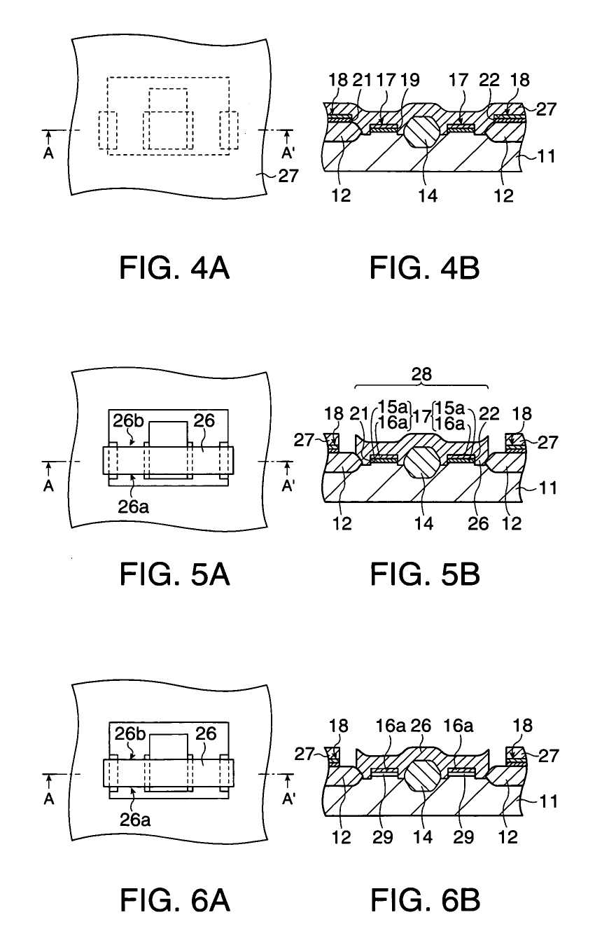

FIGS. 4A and 4B show a process that forms a support formation layer 27 for forming a support 26 (refer to FIGS. 5A and 5B) over the entire surface above the silicon substrate 11 in such a manner to cover support holes 21, 22 and 19, the silicon layer 16 and the second isolation layer 14.

The support formation layer 27 is, for example, a silicon oxide film (SiO₂).

Initially, the resist pattern used in the previous process is removed.

Next, the support formation layer 27 made of a silicon oxide film (SiO₂) or the like is deposited over the entire surface above the silicon substrate 11 by CVD or the like in such a manner to bury the first support hole 21, the second support hole 22 and the third support hole 19, and to cover the silicon layer 16.

FIGS. 5A and 5B show a process that removes part of the support formation layer 27 except for the support formation region 28, which is the region for forming the support 26, thereby completing the support 26.

The way to remove the part of the support formation layer 27 is etching using a resist pattern (not shown) as the mask.

The resist pattern is such that part thereof is open except for the area corresponding to the planar surface of the support 26.

Further, by using the same resist pattern as the mask, part of the single-crystal epitaxial film 17 and part of the polycrystalline epitaxial film 18 located in the area other than the support formation region 28 are etched away.

As described above, the support 26, with a first side 26a and a second side 26b thereof exposed (for both, refer to FIG. 5A), is formed from the support formation layer 27.

The end face of the single-crystal epitaxial film 17 has portions located beneath the support 26.

The portions are kept in tight contact with the support 26.

The sides (edges) of the single-crystal epitaxial film 17 under the first side 26a and the second side 26b of the support 26 are exposed surfaces where the first silicon layer 16a and the first silicon germanium layer 15a are exposed.

In addition, the first support hole 21 and the second support hole 22 separate the polycrystalline epitaxial film 18 on the first isolation layer 12 from the single-crystal epitaxial film 17 on the silicon substrate 11.

Therefore, it can be prevented that the crystal defect of the polycrystalline epitaxial film 18 affects the single-crystal epitaxial film 17.

FIGS. 6A and 6B show a process that selectively removes the first silicon germanium layer 15a located under the support 26 (refer to FIG. 5B) by, for example, wet etching.

Initially, the resist pattern used in the previous process is removed.

Next, an etchant such as fluoro-nitric acid is brought into contact with the single-crystal epitaxial film 17 located under the support 26 (refer to FIG. 5B).

At this point, etching is performed from the portions where the single-crystal epitaxial film 17 is exposed (exposed surfaces located under the first side 26a and the second side 26b of the support 26).

The first silicon layer 16a has an etch selectivity less than that of the first silicon germanium layer 15a.

It is therefore possible to perform selective etching to remove the first silicon germanium layer 15a, leaving behind the first silicon layer 16a.

The above-described process results in forming a hollow cavity 29 between the silicon substrate 11 and the first silicon layer 16a (under the first silicon layer 16a) with the first silicon layer 16a supported by the support 26.

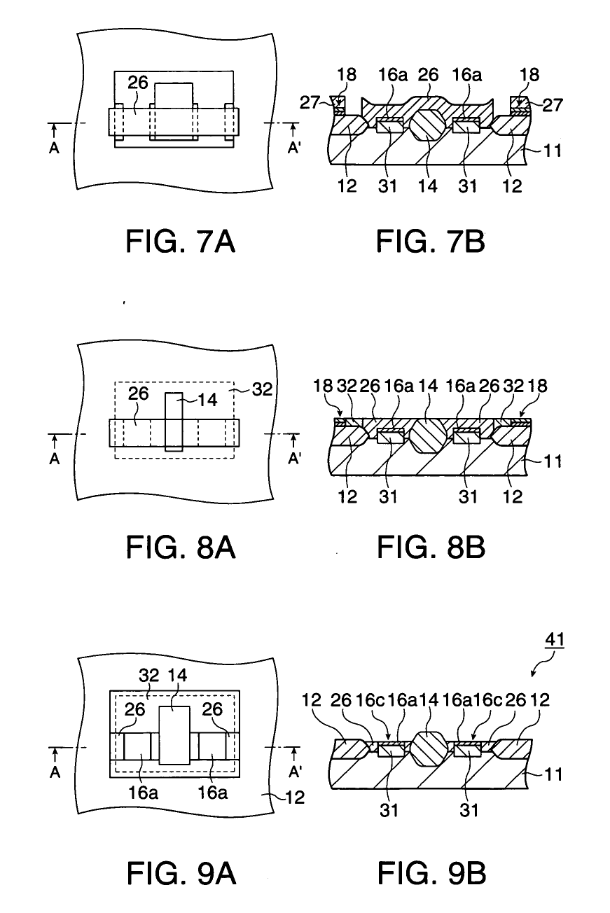

FIGS. 7A and 7B show a process that forms a buried insulating layer (BOX layer: Buried Oxide layer) 31 in the cavity 29 (refer to FIGS. 6A and 6B).

The buried insulating layer 31 is, for example, a silicon oxide film and is formed by thermal oxidation in which silicon contained in the silicon substrate 11 and the first silicon layer 16a reacts with oxygen.

FIGS. 8A and 8B show a process that buries an insulating film 32 into the portions needed on the silicon substrate 11, and planarizes the surface above the silicon substrate 11.

Initially, the insulating film 32 made of a silicon oxide film is formed over the entire surface above the silicon substrate 11 in order to electrically insulate the SOI element.

The insulating film 32 is formed by, for example, CVD.

Next, the entire surface above the silicon substrate 11 is planarized by CMP polishing using the polycrystalline epitaxial film 18 on the first isolation layer 12 and the second isolation layer 14 as stopper layers (planarization process).

Thereby, part of the insulating film 32, part of the support 26 and part of the support formation layer 27 are removed.

FIGS. 9A and 9B show a process that completes a semiconductor substrate 41.

Initially, part of the unnecessary support 26 above the first silicon layer 16a, part of the insulating film 32, and the support formation layer 27 on the second silicon layer 16b are removed.

The top surface 16c of the first silicon layer 16a is thereby exposed.

Then, the polycrystalline epitaxial film 18 is removed.

The above-described process results in forming a structure in which, on the silicon substrate 11, the first silicon layer 16a is isolated by the insulating film 32 and the buried insulating layer 31 (SOI structure).

As a result, the semiconductor substrate 41 is completed.

As described above, according to the method of manufacturing the semiconductor substrate 41, the first support hole 21 and the second support hole 22 are formed at the boundary of the first isolation layer 12 and the SOI element formation region 13.

The areas of the support holes 21 and 22 occupied in the SOI element formation region 13 (areas of the portions of the support holes 21 and 22 located within the SOI element formation region 13) can therefore be made small as compared to the case where the support holes 21 and 22 are formed within the SOI element formation region 13.

This enables the area of the SOI element formation region 13 to be made smaller, thereby making the semiconductor substrate 41 smaller.

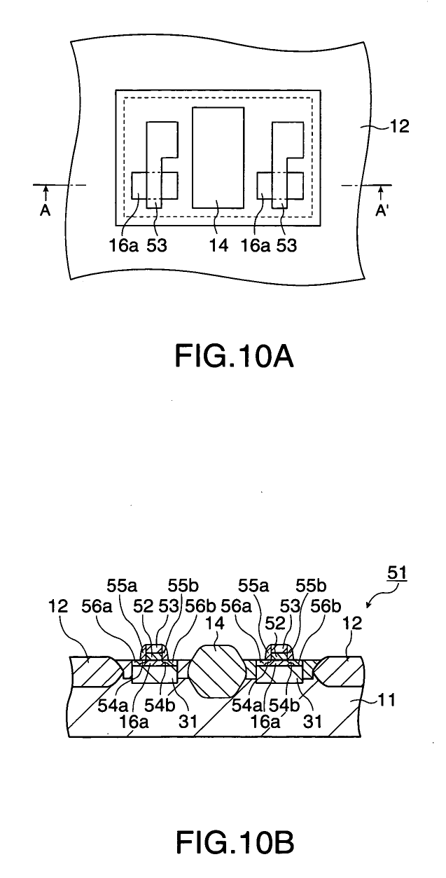

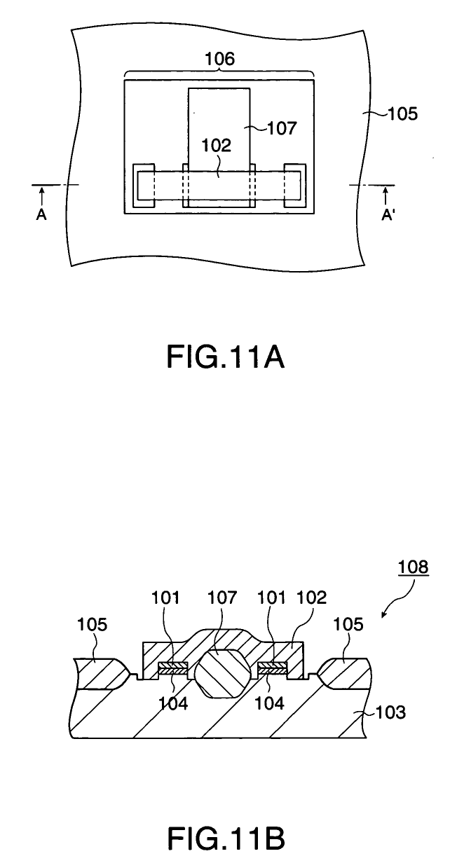

FIGS. 10A and 10B are schematic views showing a method of manufacturing a semiconductor device and the configuration of a semiconductor device.

FIG. 10A is a schematic plan view and FIG. 10B is a schematic sectional view taken along the line A-A′ of FIG. 10A.

The method of manufacturing a semiconductor device and the configuration of a semiconductor device will be described with reference to FIGS. 10A and 10B.

The manufacturing method of a semiconductor device follows the manufacturing method of a semiconductor substrate that has been described with reference to FIGS. 1A through 9B.

FIGS. 10A and 10B show a process that completes a semiconductor device 51.

Initially, the surface of the first silicon layer 16a is thermally oxidized to form a gate insulating film 52 at the surface of the first silicon layer 16a.

A polysilicon layer is then formed on the gate insulating film 52 by, for example, CVD.

Thereafter, the polysilicon layer is patterned by the use of a photolithography technique, thus forming a gate electrode 53 on the gate insulating film 52.

Next, impurities such as arsenic (As), phosphorus (P) and boron (B) are ion implanted into the first silicon layer 16a using the gate electrode 53 as a mask, thereby forming lightly doped drain (LDD) layers 54a and 54b, which are made of lightly-doped layers, located within the first silicon layer 16a at the both sides of the gate electrode 53.

An insulating layer is formed on the first silicon layer 16a having the LDD layers 54a and 54b formed therein by, for example, CVD, and then is etched back using dry etching such as reactive ion etching (RIE), thereby forming sidewalls 55a and 55b on the side walls of the gate electrode 53.

Then, impurities such as As, P and B are ion implanted into the first silicon layer 16a using the gate electrode 53 and sidewalls 55a and 55b as masks.

Source/drain electrode layers 56a and 56b made of highly-doped layers are thereby formed laterally proximate the sidewalls 55a and 55b in the first silicon layer 16a, resulting in the completion of a transistor.

In addition, a bulk element is formed in a bulk element formation region, thus completing the semiconductor device 51 having an SOI element and a bulk element together provided on the silicon substrate 11.

As a result, the process can provide the manufacturing method of the semiconductor device 51 and the semiconductor device 51 that allow the size of the semiconductor device 51 to be made smaller.

Effects described below are achieved, as have been described above in detail, according to a manufacturing method of a semiconductor substrate, a manufacturing method of a semiconductor device and a semiconductor device of the present embodiment.

(1) According to the embodiment, the first support hole 21 and the second support hole 22 are formed at the boundary of the first isolation layer 12 and the SOI element formation region 13, making it possible for the areas of the first and second support holes 21 and 22 occupied in the SOI element formation region 13 to be made small as compared to the case where the support holes 21 and 22 are formed within the SOI element formation region 13.

This enables the area of the SOI element formation region 13 to be made smaller, thereby making the semiconductor device 51 smaller.

In addition, the number of the semiconductor devices 51 that can be made from one substrate can be increased, leading to, for example, improvement in yield.

(2) According to the embodiment, the contact portion between the polycrystalline epitaxial film 18 formed on the first isolation layer 12 and the single-crystal epitaxial film 17 formed on the silicon substrate 11 can be divided by forming the support holes 21 and 22 at the boundary of the first isolation layer 12 and the SOI element formation region 13.

It is therefore possible to reduce adverse effects of the crystallinity of the polycrystalline epitaxial film 18 on the single-crystal epitaxial film 17.

(3) According to the embodiment, the second isolation layer 14 is formed within the SOI element formation region 13.

Therefore, in the planarization process (CMP polishing), the second isolation layer 14 as well as the polycrystalline epitaxial film 18 formed on the first isolation layer 12 can suppress the excessive removal of the first silicon layer 16a.

It should be noted that the embodiment is not limited to the above, but may be practiced in the following embodiments.

### First Modification

While silicon is used as the material of the semiconductor base in the above description, the embodiment is not limited to this.

For example, Ge, SiGe, SiC, SiSn, PbS, GaAs, InP, GaP, GaN, ZnSe and the like may be used as the material.

### Second Modification

The above description takes an example in which silicon germanium is used as the first semiconductor layer material, and silicon as the second semiconductor layer material.

However, it is sufficient if materials are combined such that the second semiconductor layer has an etch selectivity less than that of the first semiconductor layer.

For example, combinations selected from Ge, SiC, SiSn, PbS, GaAs, InP, GaP, GaN, ZnSe and the like may be used as the materials of the first and second semiconductor layers.

What is claimed is:

1. A method of manufacturing a semiconductor substrate, comprising:
forming a first isolation layer for isolating an element region from another region on a semiconductor base;
forming a first semiconductor layer on the semiconductor base;
forming a second semiconductor layer on the first semiconductor layer, the second semiconductor layer having an etch selectivity less than an etch selectivity of the first semiconductor layer;
forming a support hole by removing a portion of the second semiconductor layer and a portion of the first semiconductor layer each corresponding to the support hole;
forming a support formation layer above the semiconductor base so as to cover the support hole and the second semiconductor layer;
forming a support and an exposed surface for exposing part of an end of each of the first semiconductor layer and the second semiconductor layer by etching an area other than an area including the support hole and the element region therein, the first semiconductor layer and the second semiconductor layer being located under the support;
forming a cavity between the second semiconductor layer in the element region and the semiconductor base by etching away the first semiconductor layer through the exposed surface;
forming a buried insulating layer in the cavity; and
performing planarization above the second semiconductor layer to remove part of the support located on the second semiconductor layer;
wherein the forming a support hole forms a first support hole at a boundary between the element region and the first isolation layer.

2. A method of manufacturing a semiconductor substrate, comprising:
forming on a semiconductor base a first isolation layer for isolating an element region from another region and forming within the element region a second isolation layer for being used as a stopper layer;
forming a first semiconductor layer on the semiconductor base;
forming a second semiconductor layer on the first semiconductor layer, the second semiconductor layer having an etch selectivity less than an etch selectivity of the first semiconductor layer;
forming a support hole by removing a portion of the second semiconductor layer and a portion of the first semiconductor layer each corresponding to the support hole;
forming a support formation layer above the semiconductor base so as to bury the support hole and to cover the second semiconductor layer;
forming a support and an exposed surface for exposing part of an end of each of the first semiconductor layer and the second semiconductor layer by etching an area other than an area including the support hole and the element region therein, the first semiconductor layer and the second semiconductor layer being located under the support;
forming a cavity between the second semiconductor layer in the element region and the semiconductor base by etching away the first semiconductor layer through the exposed surface;
forming a buried insulating layer in the cavity; and
performing planarization above the second semiconductor layer by using at least the second isolation layer to remove part of the support located on the second semiconductor layer;
wherein the forming a support hole forms a first support hole at a boundary between the element region and the first isolation layer.

3. The method of manufacturing a semiconductor substrate according to claim 2, wherein the forming a support hole forms a second support hole in an area including the second isolation layer.

4. The method of manufacturing a semiconductor substrate according to claim 1, wherein:
the first semiconductor layer is a silicon germanium layer; and
the second semiconductor layer is a silicon layer.

5. A method of manufacturing a semiconductor device, comprising forming a transistor in the second semiconductor layer after performing the method of manufacturing a semiconductor substrate according to claim 1.

6. A semiconductor device having an SOI structure comprising:
a buried insulating layer formed on a semiconductor base, the buried insulating layer being buried to replace a first semiconductor layer;
a second semiconductor layer formed on the buried insulating layer;
a support for supporting the second semiconductor layer; and
a first support hole for forming the support formed at a boundary of an element region and a first isolation layer.
